(19) United States
(12) Patent Application Publication
(10) Pub. No.: US 2009/0045479 A1
(43) Pub. Date: Feb. 19, 2009

(54) Image sensor with vertical drain structures

(76) Inventors: Jeong-Hoon Bae, Seoul (KR); Tae-Seok Oh, Seoul (KR); Ki-Hong Kim, Yongin-si (KR); Won-Je Park, Yongin-si (KR)

Correspondence Address: LAW OFFICE OF MONICA H CHOI, P O BOX 3424, DUBLIN, OH, 430160204, US

(21) Appl. No.: 12/012,348

(22) Filed: Feb. 1, 2008

(30) Foreign Application Priority Data
Feb. 2, 2007 (KR) 2007-11088

(51) Int. Cl. H01L 27/144

(52) U.S. Cl. 257/443; 257/E27.129

(57) ABSTRACT

An image sensor includes an array of photo-detectors, a plurality of conductive line regions, and a conductive junction region. The array of photo-detectors is formed in a semiconductor substrate. Each conductive line region is formed under a respective line of photo-detectors along a first direction in the substrate. The conductive junction region is formed between the array of photo-detectors and the plurality of conductive line regions in the substrate. The conductive line regions and the conductive junction region form vertical drain structures for the photo-detectors.

This application claims priority under 35 USC § 119 to Korean Patent Application No. 2007-11088 filed on Feb. 2, 2007 in the Korean Intellectual Property Office, the disclosure of which is incorporated herein in its entirety by reference.

### BACKGROUND OF THE INVENTION

1. Field of the Invention

The present invention relates generally to image sensors, and more particularly, to an image sensor with vertical drain structures formed under the photo-detectors of the image sensor.

2. Background of the Invention

An image sensor converts an optical image into electrical signals during use in electronic devices such as digital cameras for example. An image sensor includes a pixel array including a plurality of pixels arranged in a matrix of rows and columns.

Each of the pixels includes a respective photo-detector for receiving incident photons to generate signal charges. Each pixel also includes transistors for transmitting and outputting the signal charges generated at the photodetector.

Each pixel may have one of three types of structures such as a 1-transistor structure, a 2-transistor structure, or a 3-transistor structure, as known to one of ordinary skill in the art. The 1-transistor structure has a high fill factor with a fill factor being a ratio of the area of a photo-detector to the entire area.

Because a higher fill factor results in better sensitivity of light, the 1-transistor structure has higher light sensitivity but suffers from strong noise. For this reason, the 4-transistor structure is widely used but is more difficult for integration of an image sensor.

Accordingly, an image sensor is desired to have high integration with a high fill factor and low noise.

### SUMMARY OF THE INVENTION

Accordingly, an image sensor is formed with vertical drain structures for achieving high integration, high fill factor, and low noise.

An image sensor according to an embodiment of the present invention includes an array of photo-detectors, a plurality of conductive line regions, and a conductive junction region. The array of photo-detectors is formed in a semiconductor substrate. The plurality of conductive line regions is formed in the semiconductor substrate, and each conductive line region is formed under a respective line of photo-detectors along a first direction. The conductive junction region is formed between the array of photo-detectors and the plurality of conductive line regions within the semiconductor substrate.

In an example embodiment of the present invention, the conductive line regions are doped with a first dopant, and the conductive junction region is doped with a second dopant that is of opposite conductivity from the first dopant.

In a further embodiment of the present invention, each photo-detector has a respective junction region doped with a third dopant of the same conductivity type as the first dopant. In addition, the semiconductor substrate is doped with a fourth dopant of the same conductivity type as the second dopant.

For example, the semiconductor substrate is P type doped, the conductive line regions are N+ type doped, the conductive junction region is P+ type doped, and the respective junction regions of the photo-detectors are N type doped.

In another embodiment of the present invention, each photo-detector has a respective top junction region doped with a fifth dopant of the opposite conductivity type as the third dopant. For example, the respective top junction regions of the photo-detectors are P type doped.

In a further embodiment of the present invention, the image sensor also includes a surrounding junction that surrounds the array of photo-detectors. For example, the surrounding junction is P+ type doped.

In another embodiment of the present invention, the conductive junction region is separated from the conductive line regions by a material of the semiconductor substrate.

In a further embodiment of the present invention, the conductive junction region surrounds a portion of the conductive line regions such as a respective top surface and respective side portions of each conductive line region with inclined surfaces of the conductive junction region.

In another embodiment of the present invention, the array of photo-detectors includes a respective transmission transistor coupled to the respective junction region of each of the photo-detectors. For example, the respective transmission transistor is a respective field effect transistor.

In a further embodiment of the present invention, the image sensor includes at least one respective conductive plug formed onto each of the conductive line regions for making contact to the respective conductive line region. For example, two respective conductive plugs are formed onto two ends of each conductive line region. Alternatively, a conductive plug is formed onto a plurality of conductive line regions. In addition, a respective impurity diffusion layer surrounds each conductive plug.

In another embodiment of the present invention, the image sensor includes an overlying conductive fine coupled to a line of conductive plugs disposed along a second direction that is perpendicular to the first direction.

In an example embodiment of the present invention, the conductive plugs and the overlying conductive line are formed outside of the surrounding junction around the array of photo-detectors.

In this manner, the plurality of conductive line regions and the conductive junction region form vertical drain structures for the photo-detectors. Such structures may be used for resetting the photo-detectors and for drainage of extra electrons for reducing blooming in the photo-detectors.

### BRIEF DESCRIPTION OF THE DRAWINGS

The above and other features and advantages of the present invention will become more apparent when described in detailed exemplary embodiments thereof with reference to the attached drawings in which:

FIG. 1 is a top plan view of an image sensor with vertical drain structures according to an example embodiment of the present invention;

FIGS. 2A, 2B, and 2C are cross-sectional views along lines I-I′, II-II′, and III-III′, respectively in FIG. 1, according to an example embodiment of the present invention;

FIG. 3 is a cross-sectional view along line III-III′ in FIG. 1 according to another embodiment of the present invention;

FIGS. 4A, 5A, 6A, 7A, 8A, 9A, and 10A are cross-sectional views along line I-I′ in FIG. 1 illustrating steps during fabrication of the image sensor of FIG. 1, according to an embodiment of the present invention;

FIGS. 4B, 5B, 6B, 7B, 8B, 9B, and 10B are cross-sectional views along line II-II′ in FIG. 1 illustrating steps during fabrication of the image sensor of FIG. 1, according to an embodiment of the present invention;

FIGS. 4C, 5C, 6C, 7C, 8C, 9C, and 10C are cross-sectional views along line III-III′ in FIG. 1 illustrating steps during fabrication of the image sensor of FIG. 1, according to an embodiment of the present invention;

FIGS. 11A and 12A are cross-sectional views along line I-I′ in FIG. 1 illustrating steps during fabrication of the image sensor of FIG. 1, according to another embodiment of the present invention;

FIGS. 11B and 12B are cross-sectional views along line II-II′ in FIG. 1 illustrating steps during fabrication of the image sensor of FIG. 1, according to another embodiment of the present invention;

FIGS. 11C and 12C are cross-sectional views along line III-III′ in FIG. 1 illustrating steps during fabrication of the image sensor of FIG. 1, according to another embodiment of the present invention; and

FIGS. 13 and 14 are cross-sectional views along line III-III′ of FIG. 1 illustrating steps during fabrication of the image sensor of FIG. 1, according to another embodiment of the present invention.

The figures referred to herein are drawn for clarity of illustration and are not necessarily drawn to scale. Elements having the same reference number in the above-identified figures refer to elements having similar structure and/or function.

### DETAILED DESCRIPTION OF THE INVENTION

The present invention is now described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity.

It will also be understood that when a layer is referred to as being “on” another layer or substrate, it can be directly on the other layer or substrate, or intervening layers may also be present. In addition, terms such as top and bottom are terms describing the positions of structures relative to each-other. Thus, a top may become a bottom and vice versa if the whole semiconductor wafer were turned upside down.

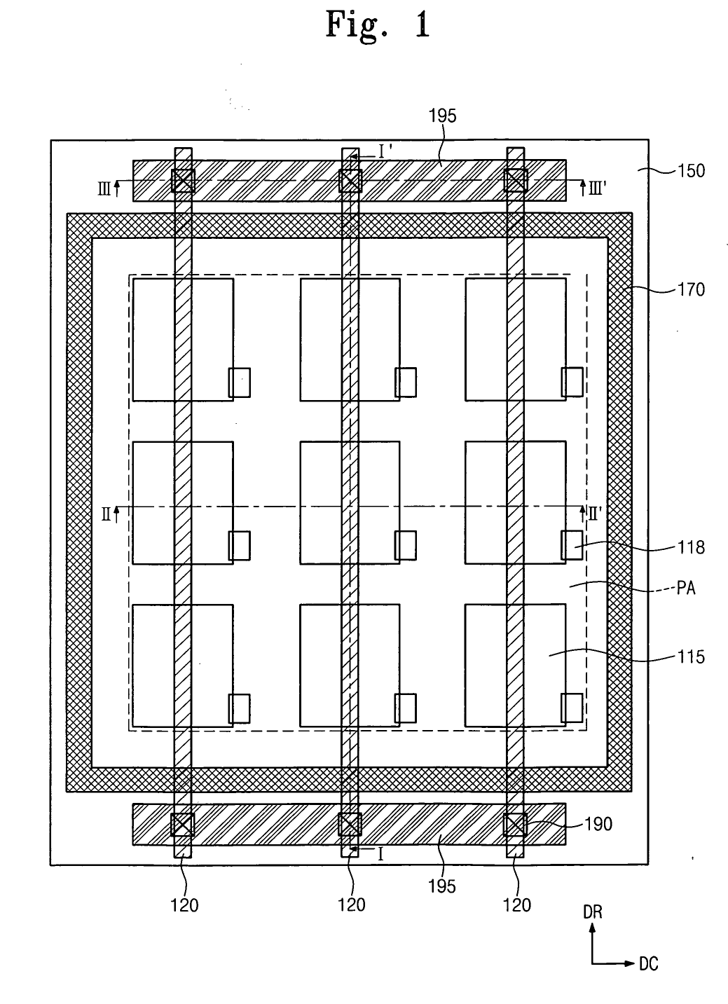

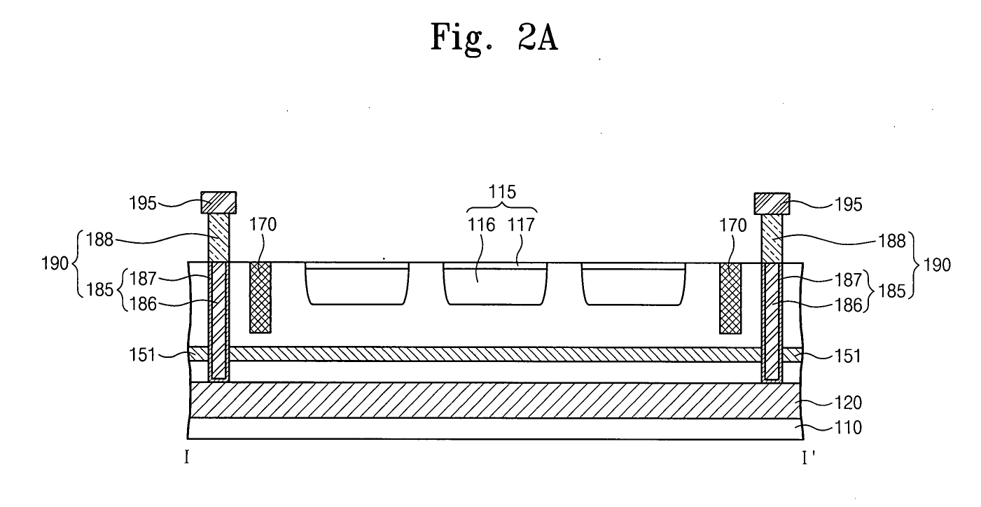

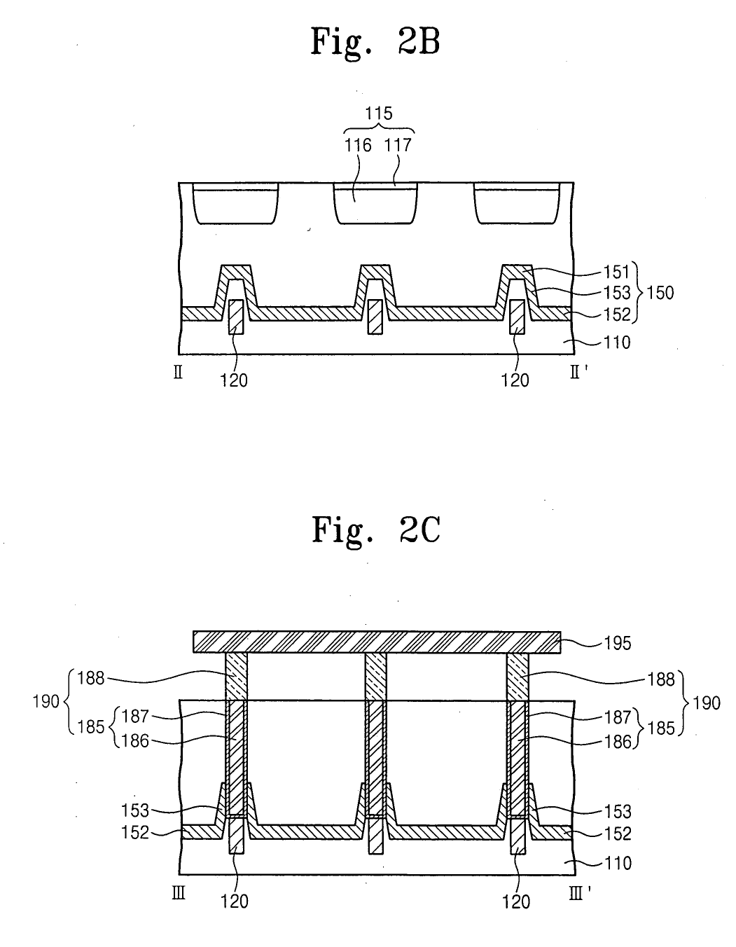

Referring to FIGS. 1, 2A, 2B, and 2C, an image sensor according to an embodiment of the present invention is formed in a semiconductor substrate 110 such as a silicon wafer for example. A pixel area PA is formed for sensing an image that may be displayed. The pixel area PA includes an array of photo-detectors 115 arranged along a first direction DR and a second direction DC. The second direction DC is perpendicular to the first direction DR.

In an example embodiment of the present invention, the substrate 110 is P type doped. In that case, each photo-detector 115 includes a respective junction region 116 that is N type doped and includes a respective top junction region 117 that is P type doped.

Each photo-detector 115 performs photoelectric conversion of received light to generate signal charges that in turn generate analog signals. The photo-detectors 115 are insulated from each other by a field isolation layer (not shown) disposed on the substrate 110 between the photo-detectors 115, in an example embodiment of the present invention.

A respective transmission gate 118 of a respective transmission field effect transistor is formed at one side of each photo-detector 115. The respective transmission field effect transistor outputs a photoelectric conversion signal generated in the photo-detector 115. In the image sensor of FIG. 1, each pixel has a 1-transistor structure with such a respective transmission field effect transistor.

In addition, a plurality of conductive line regions 120 are formed in the semiconductor substrate 110. Each conductive line region 120 is formed under a respective line of photo-detectors 115 along the first direction DR. Each conductive line region 120 is overlapped by such a line of the photo-detectors 115 along the first direction DR. For example, each conductive line region 120 is disposed along the centers of the line of photo-detectors 115 in the first direction DR.

In the example embodiment of FIG. 1, the conductive line region 120 has smaller width than the photo-detectors 115. In an alternative embodiment of the present invention, the conductive line region 120 has a larger width than the photo-detectors 115. In an example embodiment of the present invention, the conductive line regions 120 are N+ type doped. An N+ or P+ type doped region herein has a dopant concentration that is significantly higher such as twice as much or ten times as much than an N or P type doped region described herein.

A conductive junction region 150 is disposed between the photo-detectors 115 and the conductive line regions 120. The conductive junction region 150 includes a first section 151, a second section 152, and a third section 153, according to an embodiment of the present invention. The first section 151 is disposed over a top surface of the conductive line region 120, and the second section 152 is disposed from both sides of the conductive line regions 120. The third section 153 connects the first and second sections 151 and 152 to each other with an inclination toward the sides of conductive line region 120.

Portions of the second section 152 overlap under the photo-detector 115 according to an embodiment of the present invention. A bottom surface of the second section 152 is disposed lower than a top surface of the conductive line regions 120. At least a portion of the third section 153 overlaps a sidewall of the conductive line region 120. That is, the conductive junction region 150 surrounds at least a portion of the conductive line regions 120. The conductive junction region 150 is disposed within the entire area of the substrate 110 including the pixel area PA. The conductive junction region 150 is P+ type doped in an embodiment of the present invention.

A surrounding junction 170 is disposed to surround the pixel area PA in an embodiment of the present invention. The surrounding junction 170 is disposed between the pixel area PA and contacts 190 for electrically isolating the pixel area PA from the contacts 190. In an alternative embodiment of the present invention, the surrounding junction 170 is in contact with the conductive junction region 150.

In a further embodiment of the present invention, the surrounding junction 170 has the same conductivity type as the conductive junction region 150. The surrounding junction 170 is P⁺ type doped in an embodiment of the present invention. Accordingly, the image sensor has a vertical NPN drain structure comprised of the N⁺ type conductive line regions 120, the P type substrate 110, the P⁺ type conductive junction region 150, and the N type photo-detector junction regions 116.

Respective contacts 190 are disposed at both ends of each conductive line region 120. In an alternative embodiment of the present invention, a contact may be disposed only at one end of each conductive line region 120. Referring to FIGS. 2A and 2C, each contact 190 includes a bottom contact 185 and a top contact 188. The bottom contact 185 is formed through the conductive junction region 150 to contact the conductive line region 120.

The bottom contact 185 includes a contact plug 186 and an impurity diffusion layer 187. The contact plug 186 is comprised of polysilicon or metal in an embodiment of the present invention. The conductivity type of the impurity diffusion layer 187 is same as that of the conductive junction region 150 and opposite from that of the conductive junction region 150. For example, the impurity diffusion layer 187 is N type doped in an example embodiment of the present invention. The top-contact 188 is disposed on the bottom contact 185 and contacts an overlying conductive line 195.

The conductive line 195 is disposed on the contacts 190 along the second direction DC perpendicular to the first direction DR. The conductive line 195 is electrically connected to the conductive line regions 120 via the contacts 190. That is, a voltage applied on the conductive line 195 from an external power supply is provided to the conductive line regions 120 through the contacts 190. Since the conductive line regions 120 are electrically connected to each other via the conductive line 195, a voltage is applied simultaneously to the conductive line regions 120. Such a voltage may include a reset voltage and a blooming control voltage.

When a relatively high reset voltage is applied on the conductive line regions 120 through the conductive line 195, a potential barrier of the conductive junction region 150 is lowered such that electrons in the photo-detectors 115 are ejected to the conductive line regions 120. That is, the photo-detectors 115 are reset simultaneously by global electronic shuttering.

When a blooming control voltage lower than the reset voltage is applied on the conductive line regions 120 through the conductive line 195, extra electrons accumulated in the photo-detectors 115 are ejected to the conductive line regions 120 from the vertical NPN drain structures 120, 150, and 116. Accordingly, the image sensor has reduced blooming without additional transistors.

In this manner, the image sensor has high fill factor with just the 1-transistor structure while blooming is also reduced with the vertical NPN drain structures. With such a 1-transistor structure, the pixel structure of the image sensor of FIG. 1 is simplified to improve fill factor, sensitivity, and saturation but with reduced fabrication steps. Additionally with such a 1-transistor structure, the image sensor of FIG. 1 may be formed to be highly integrated.

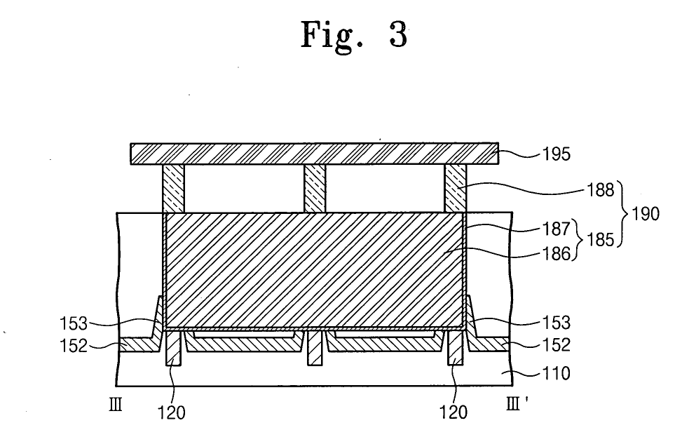

Referring to FIGS. 1 and 3, an image sensor according to another embodiment of the present invention is now described but the description of duplicate parts with the foregoing embodiment is omitted. In the embodiment of FIG. 3, the bottom contact 185 extends in the second direction DC. In that case, multiple conductive line regions 120 share one bottom contact 185. Since the conductive line regions 120 are electrically connected to each other by the bottom contact 185, they are electrically connected to the conductive line 195 irrespective of the number of the top contacts 188. Accordingly, the number of the top contacts 188 may be decided considering the electrical resistance between the conductive line regions 120 and the conductive line 195.

A method of fabricating the image sensor of FIG. 1 is now described below with reference to FIGS. 1, 4A, 5A, 6A, 7A, 8A, 9A, 10A, 4B, 5B, 6B, 7B, 8B, 9B, 10B, 4C, 5C, 6C, 7C, 8C, 9C, and 10C.

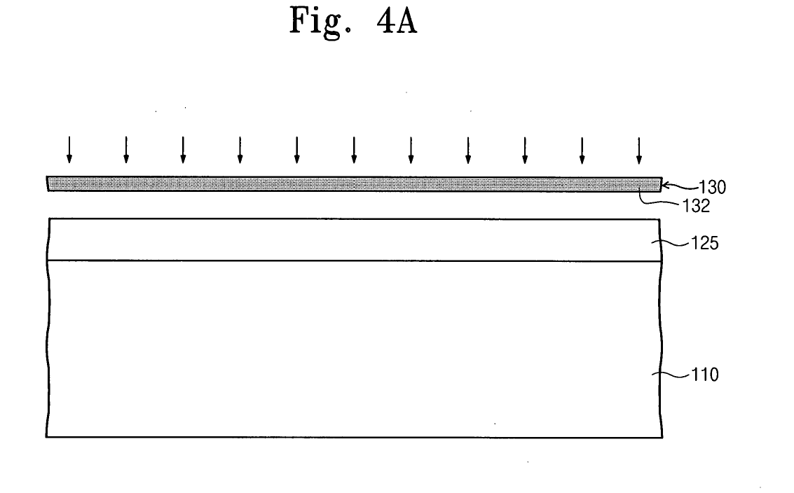

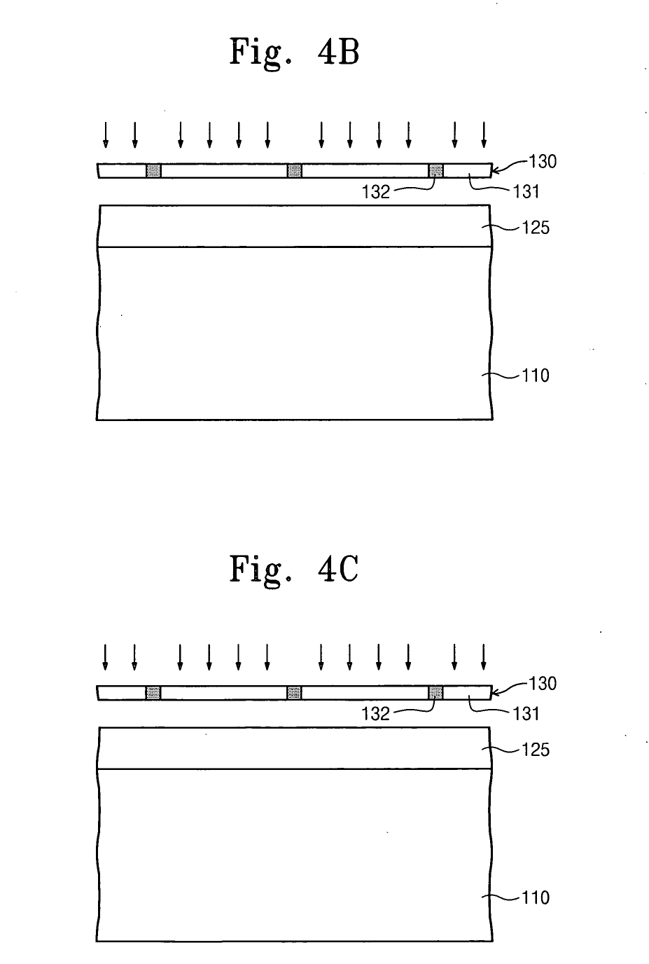

Referring to FIGS. 1, 4A, 4B, and 4C, the semiconductor substrate 110 is a P type doped silicon substrate in an example embodiment of the present invention. A photo mask 130 is disposed over and separated from a photo-resist layer 125 of a negative type. An exposure process is performed with the photo mask 130 including transmitting parts 131 and shielding parts 132. From such exposure, portions of the photo-resist layer 125 disposed under the transmitting part 131 and thus exposed to light are transformed to not melt in a developer. On the other hand if the photo-resist layer 125 were of a positive type, the transmitting parts and the shielding parts of a photo mask would be interchanged.

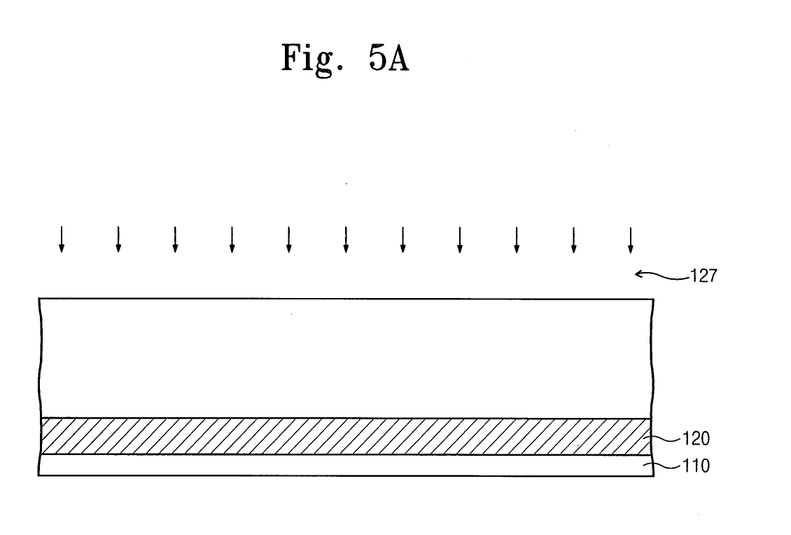

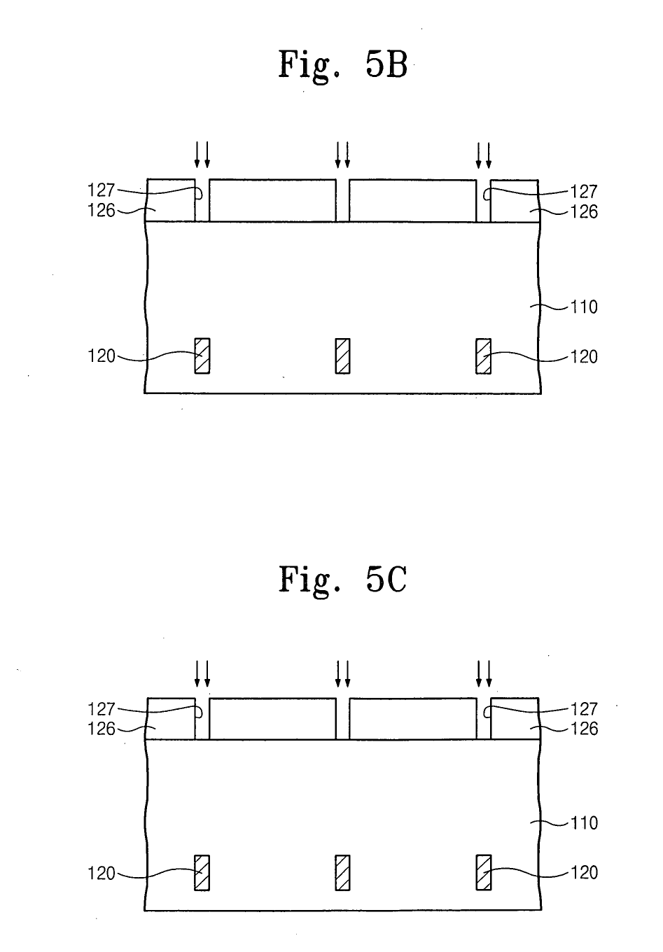

Referring to FIGS. 1, 5A, 5B, and 5C, the exposed photo-resist layer 125 is developed to form a photo-resist pattern 126. From such development, the portions of the non-exposed photo-resist layer 125 are removed to form openings 127.

Subsequently, an ion implantation is performed using the photo-resist pattern 126 as an implantation mask for forming the conductive line regions 120 that extend along the first direction DR within the substrate 110. The conductive line regions 120 are formed according to the pattern of the photo-resist pattern 126 with the conductive line regions 120 formed where the implantation dopant is passed through the openings 127 and blocked by the remaining photo-resist from suitable ion implantation conditions. The implantation dopant is N-type, and the conductive line regions 120 are N+ type doped. After formation of the conductive line regions 120, the photo-resist pattern 126 is removed.

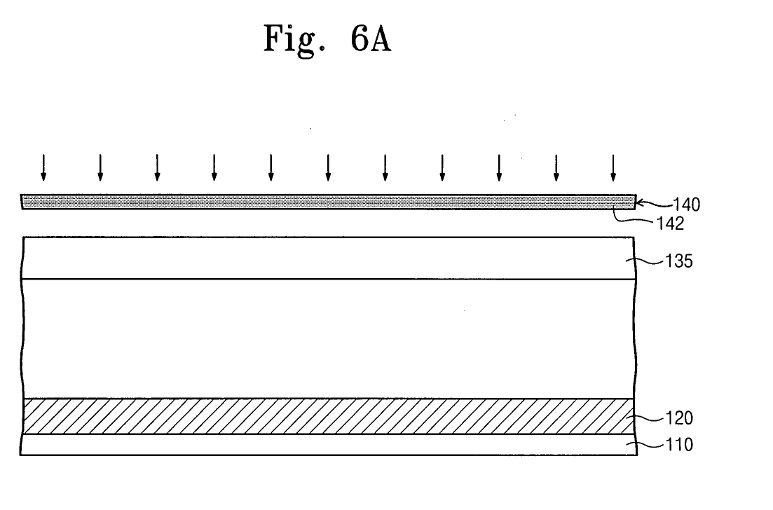

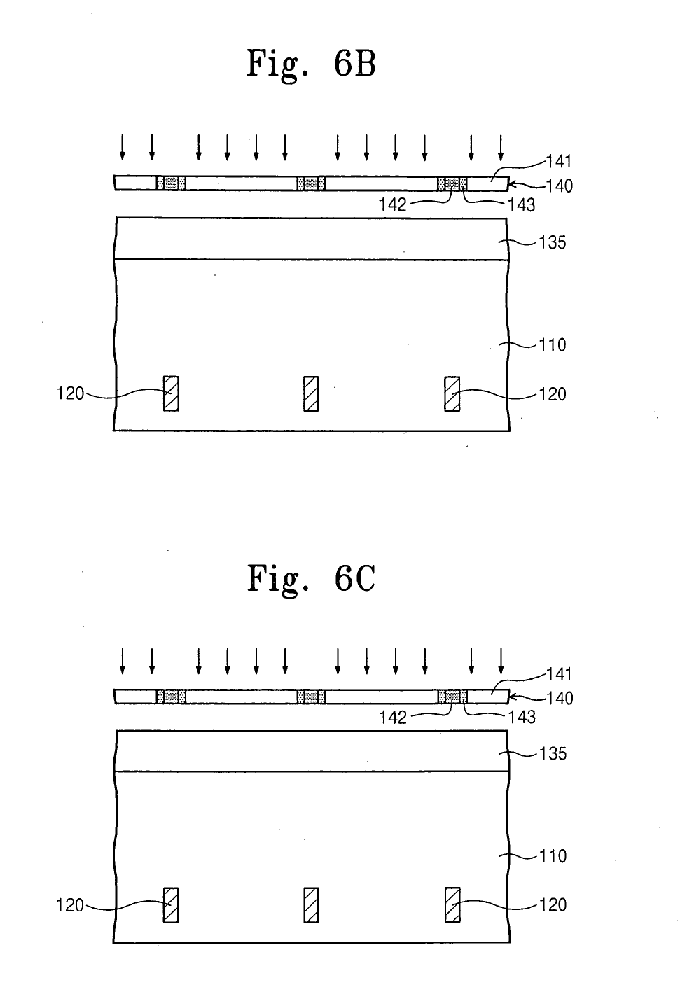

Referring to FIGS. 1, 6A, 6B, and 6C, another photo-resist layer 135 is formed on the semiconductor substrate 110. A photo mask 140 is disposed over but spaced apart from the photo-resist layer 135 that is of a positive type. The photo mask 140 includes transmitting parts 141, shielding parts 142, and semi-transmitting parts 143. The semi-transmitting parts 143 transmit some light but a smaller amount of light than the transmitting parts 141.

An exposure process is performed with the photo mask 140. From such exposure, the portions of the photo-resist layer 135 disposed under the transmitting parts 141 and exposed to light are transformed to melt in a developer. Further, the portions of the photo-resist layer 135 disposed under the semi-transmitting parts 143 are also transformed to melt in the developer but with a lower rate of melting than the portions disposed under the transmitting parts 141. The present invention may also be practiced when the photo-resist layer 135 is of a negative type. In that case, the transmitting parts and the shielding parts of a photo mask would be interchanged.

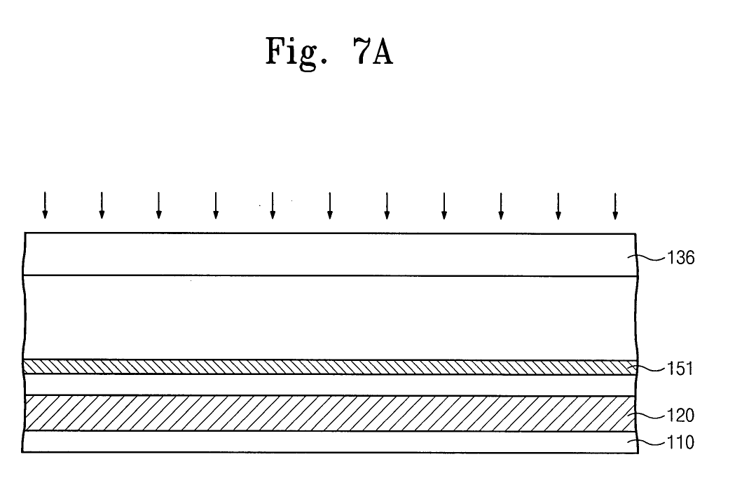

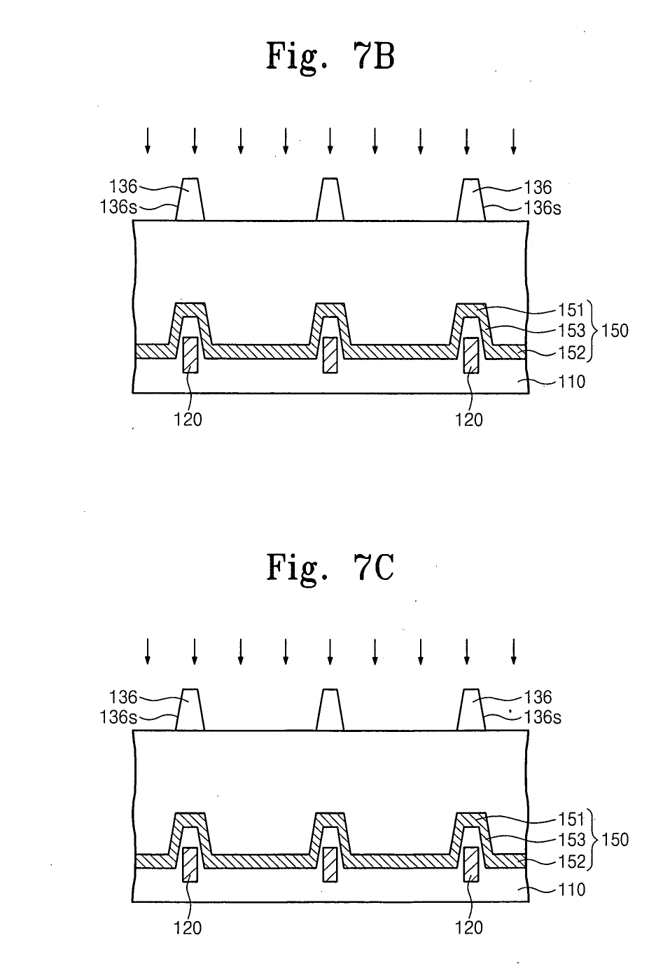

Referring to FIGS. 1, 7A, 7B, and 7C, the exposed photo-resist layer 135 is developed to form a photo-resist pattern 136. From such development, the portions of the photo-resist layer 135 that were disposed under the transmitting parts 141 are completely removed while the portions that were disposed under the semi-transmitting parts 143 are partially removed. Accordingly, sidewalls 136s of the photo-resist pattern 136 corresponding to the semi-transmitting parts 143 are formed to be inclined or to be thinner than the portions corresponding to the transmitting parts 141. The photo-resist patterns 136 are formed to remain over conductive line regions 120.

Subsequently, an ion implantation process is performed using the photo-resist pattern 136 as an ion implantation mask to form the conductive junction region 150 within the semiconductor substrate 110. The conductive junction region 150 surrounds at least a portion of the conductive line regions 120 with the conductive junction region 150 being formed at the entire area of the substrate 110 including the pixel area PA.

Ion implantation conditions are selected such that the implantation dopant passes through the photo-resist pattern 136. The implantation depth varies depending on the photo-resist pattern 136 to result in the conductive junction region 150. Thus, the conductive junction region 150 includes a first portion 151, a second portion 152, and a third portion 153 with different implantation depths.

The first portion 151 is formed most shallow within the substrate 110 because the implantation dopant passes through the photo-resist pattern 136. The second portion 152 is most deep within the substrate 110 because the implantation dopant does not pass through any photo-resist of the photo-resist pattern 136. In an example embodiment of the present invention, a bottom surface of the second portion 152 is lower than a top surface of the conductive line regions 120.

The third portion 153 is formed with depths between the first and second portions 151 and 152 to be inclined from the implantation dopant passing through the corresponding inclined sidewalls 136s of the photo-resist pattern 136. The third portion 153 is formed to connect the first portion 151 with the second portion 152. The implantation dopant is P type, and the conductive junction region 150 is P+ type doped. The conductive junction region 150 is separated from the conductive line regions 120 by the material of the semiconductor substrate 110.

Unlike the embodiments of the present invention, if the conductive line regions 120 were to be more deeply formed, the implantation dopants would be implanted at higher energy. In that case, a photo-resist pattern would be thicker and excessive exposure would be required during the photolithography process which may cause the photo-resist pattern to be formed incompletely. Additionally in that case, the implantation dopants of high energy would collide with the photo-resist pattern to result in contamination.

In contrast, the conductive junction region 150 of embodiments of the present invention is formed to surround at least portions of the conductive line regions 120. Thus, the conductive line regions 120 are formed at a similar depth as the conductive junction region 150. Thus, the implantation dopants are implanted at lower energy such that the photo-resist pattern 125 used for forming the conductive line regions 120 is not too thick.

After formation of the conductive junction region 150, the photo-resist pattern 136 is removed.

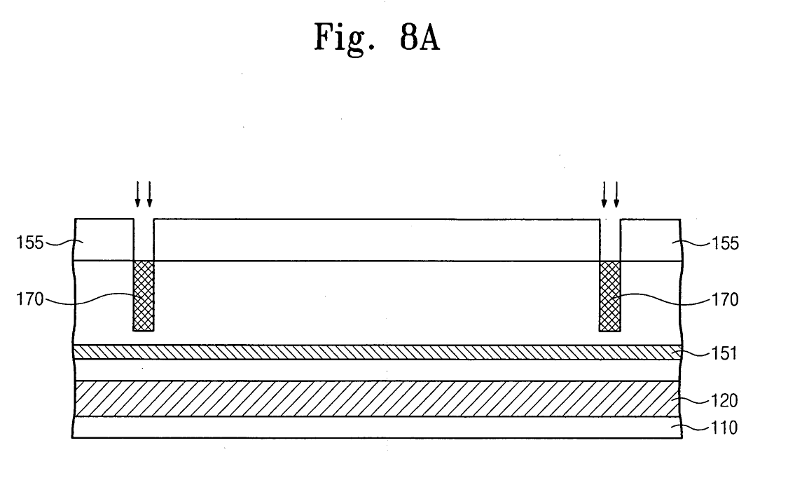

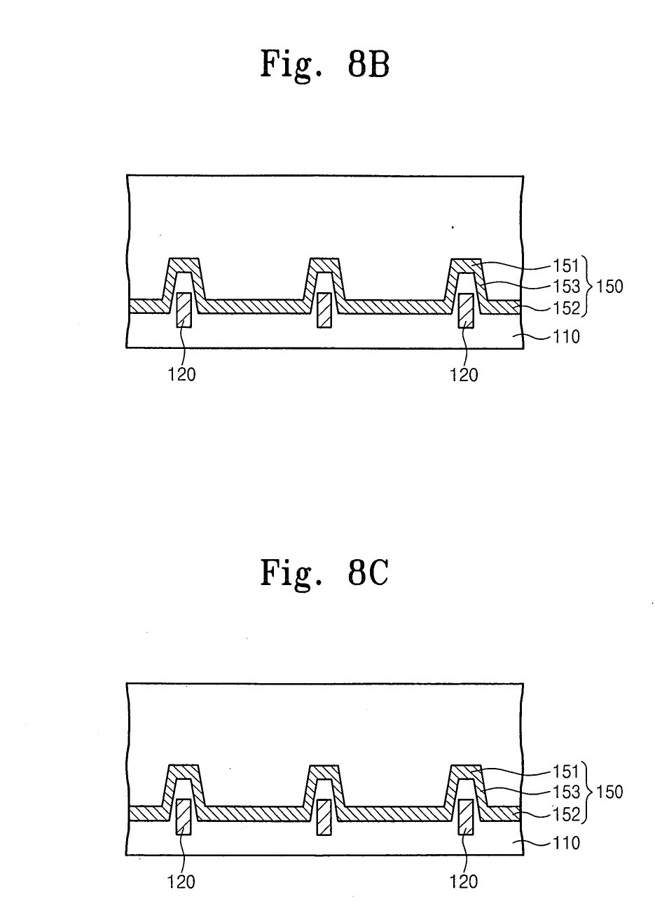

Referring to FIGS. 1, 8A, 8B, and 8C, another ion implantation mask 155 comprised of photo-resist material for example is formed on the substrate 110. Subsequently, an ion implantation process is performed to form a surrounding junction 170 disposed to surround the pixel area PA. In FIG. 8A, the surrounding junction 170 is separated from the conductive junction region 150. However, the present invention may also be practiced with the surrounding junction 170 contacting the conductive junction region 150.

The conductivity type of the surrounding junction 170 is same as that of the conductive junction region 150. The implantation dopant for the surrounding junction 170 is P type, and the surrounding junction 170 is of P+ type in an example embodiment of the present invention. After formation of the surrounding junction 170, the ion implantation mask 155 is removed.

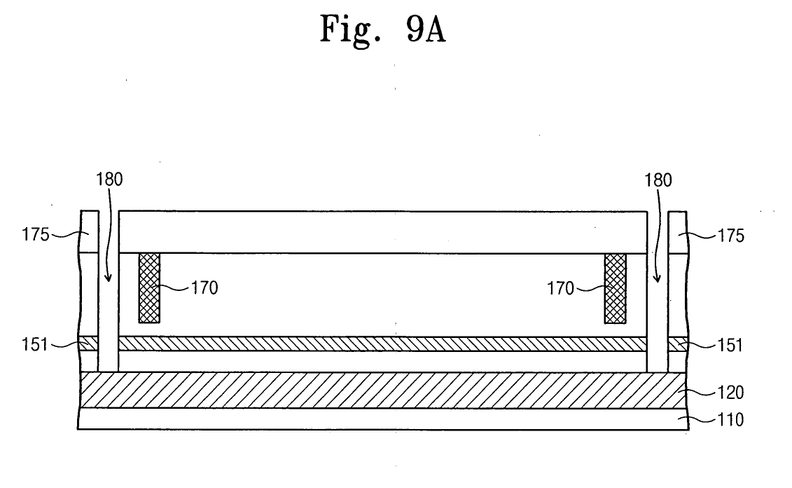

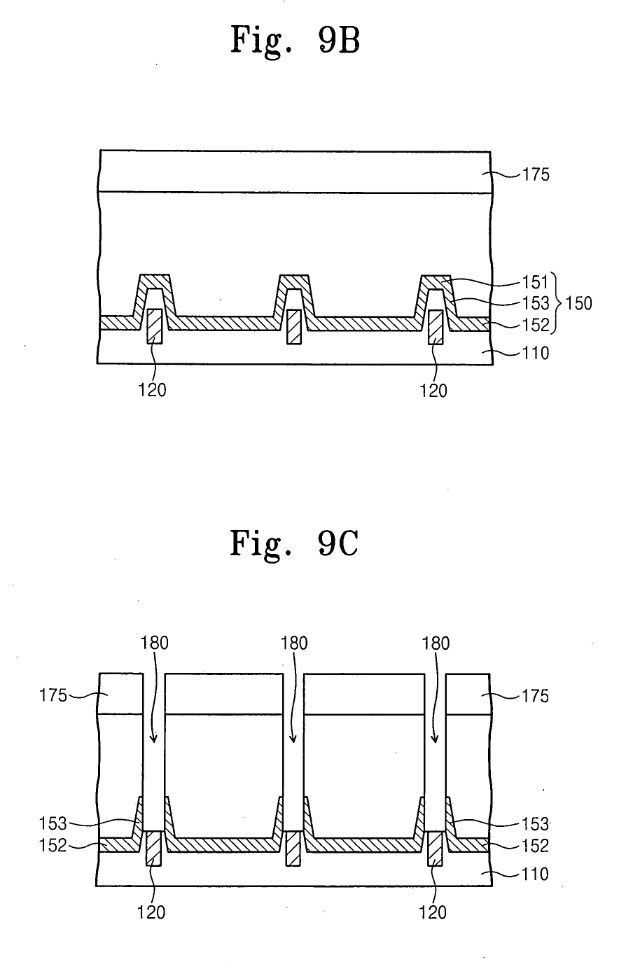

Referring to FIGS. 1, 9A, 9B, and 9C, another mask pattern 175 comprised of a photo-resist or hard-mask material for example is formed on the substrate 100. Subsequently, an etch process is performed to form openings 180 through the semiconductor substrate 110 to expose end portions of the conductive line regions 120. The openings 180 are formed through the conductive junction region 150. The present invention may be implemented with the openings 180 formed either at both ends or at one end of the conductive line regions 120.

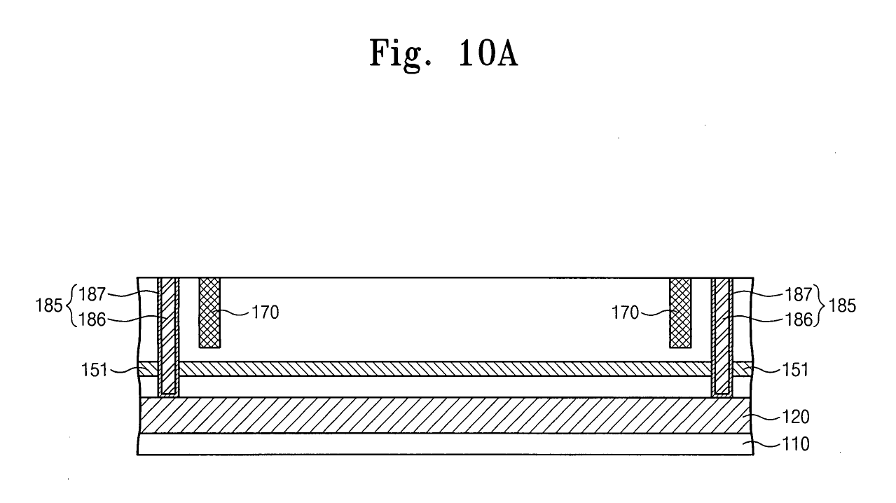

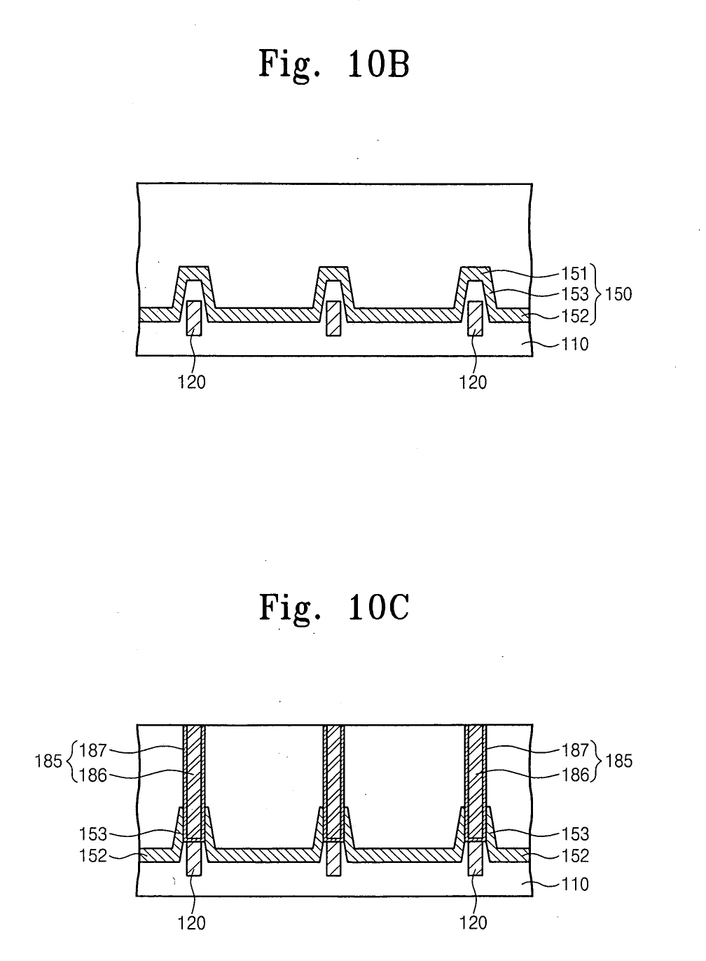

Referring to FIGS. 1, 10A, 10B, and 10C, a respective bottom contact 185 is formed within each opening 180. The bottom contact 185 includes a contact plug 186 and an impurity diffusion layer 187. The impurity diffusion layer 187 is formed to surround the contact plug 186. The impurity diffusion layer 187 has a different conductivity type such as a N+ type from the conductive junction region 150.

In one example embodiment of the present invention, the impurity diffusion layer 187 is formed after formation of the contact plug 186. For example, after filling the opening 180 with polysilicon doped with impurity ions, a planarization process is performed to form the contact plug 186. From the planarization process, the mask pattern 175 is removed until the substrate 100 is exposed. Subsequently, a thermal anneal process is performed such that the impurity ions in the contact plug 186 are diffused to form the impurity diffusion layer 187 surrounding the contact plug 186.

In another embodiment of the present invention, the contact plug 186 is formed after formation of the impurity diffusion layer 187. In that case, the impurity ions for the impurity diffusion layer 187 are implanted into the walls of the openings 180. Subsequently, the openings 180 are filled with a conductive material and a planarization process is performed to form the contact plugs 186.

Subsequently referring back to FIGS. 1, 2A, 2B, and 2C, an ion implantation process is performed to form the photo-detectors 115 in the pixel area PA. The photo-detectors 115 are arranged along the first direction DR and the second direction DC to form the array of photo-detectors 115. Both N type and P type implantation dopants are used to form the photo-detectors 115 that include the respective bottom junction regions 116 that are N type doped and the respective top junction regions 117 that are P type doped.

Additionally, the top contacts 188 are formed on the bottom contacts 185, and the conductive line 195 is formed on the top contact 188. The conductive line 195 extends along the second direction DC that is perpendicular to the first direction DR and is electrically connected to the conductive line regions 120 via the contacts 190. The conductive line regions 120 are electrically connected to each other via the conductive line 195.

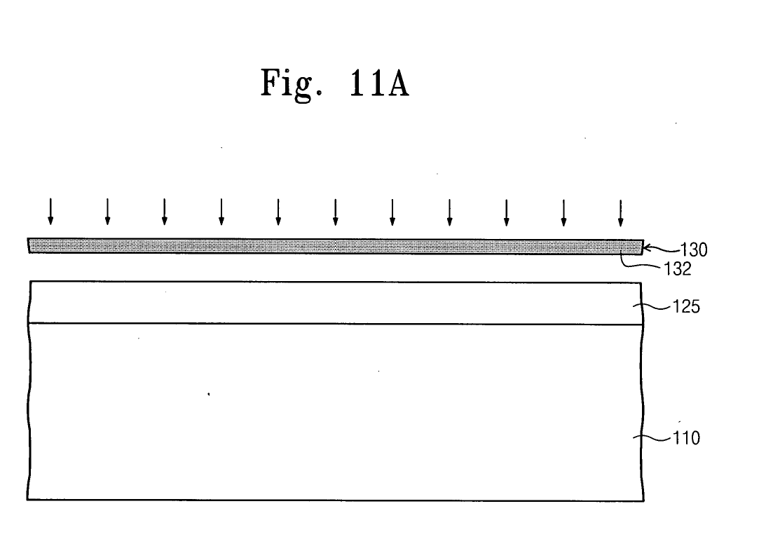

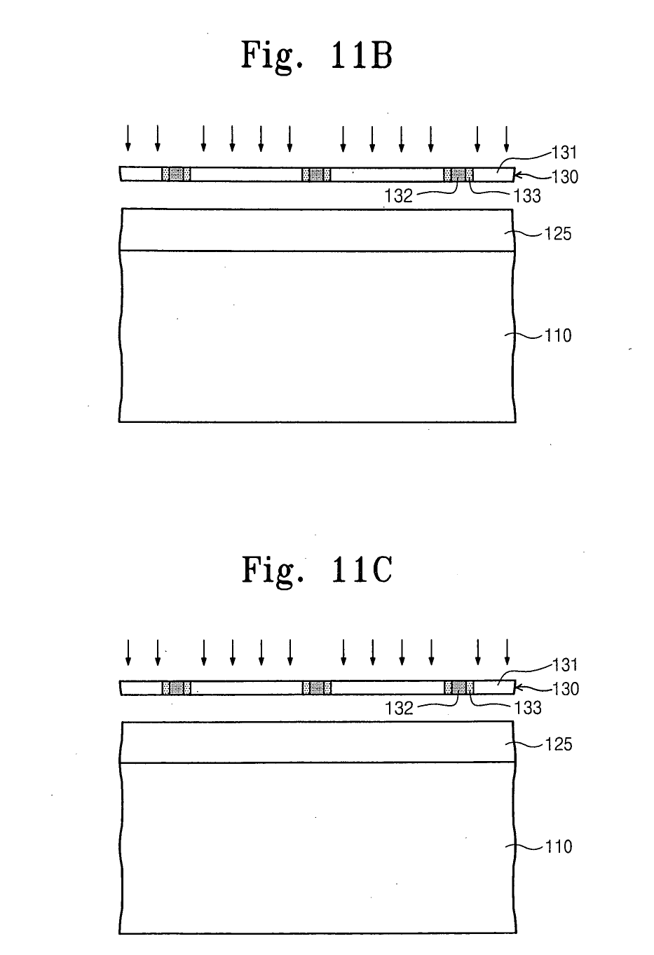

Referring to FIGS. 1, 11A, 11B, and 11C in another example embodiment of the present invention, a photo-resist layer 125 is formed on the substrate 110. The photo-resist layer 125 is of negative type for example. A photo mask 130 is formed over the photo-resist layer 125 and is spaced apart from the photo-resist layer 125. The photo mask 130 includes a transmitting part 131, a shielding part 132, and a semi-transmitting part 133. The semi-transmitting part 133 passes light but the amount of light that is passed is smaller than the light transmitted through the transmitting part 131.

An exposure process is performed using the photo mask 100 during which portions of the photo-resist layer 125 disposed under the transmitting parts 131 are exposed to light to be transformed to melt in a developer. Additionally, portions of the photo-resist layer 125 disposed under the semi-transmitting parts 133 are exposed to some light but less than the amount of light for the transmitting parts 133. Thus, the portions of the photo-resist layer 125 disposed under the semi-transmitting parts 133 are transformed to melt in the developer but with a lower rate of melting than the portions of the photo-resist layer 125 disposed under the transmitting parts 131.

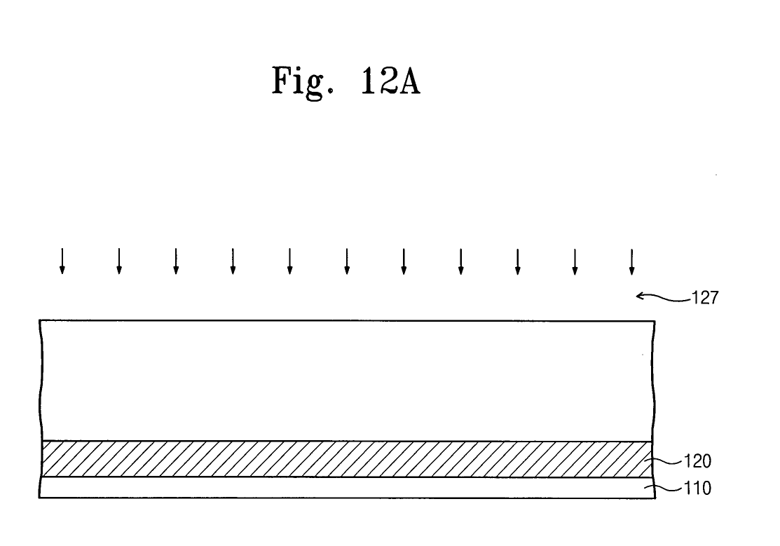

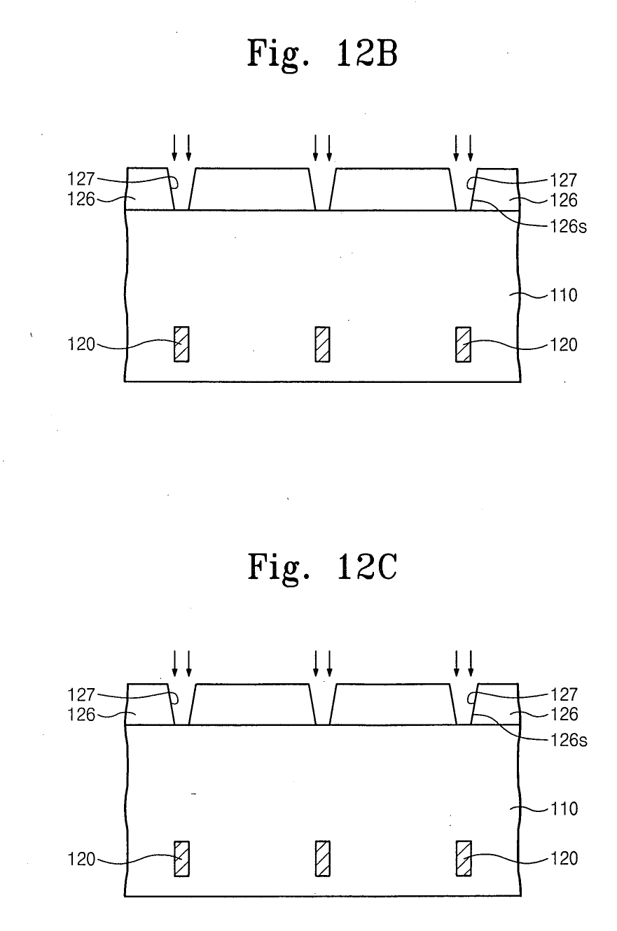

Subsequently referring to FIGS. 1, 12A, 12B, and 12C, the exposed photo-resist layer 125 is developed to form a photo-resist pattern 126. From such development, the portions of the photo-resist layer 125 disposed under the transmitting parts 131 remain while the portions of the photo-resist layer 125 disposed under the shielding parts 132 are completely removed to form openings 127. In addition, portions of the photo-resist layer 125 disposed under the semi-transmitting part 133 are partially removed such that the openings 127 are tapered down with inclined sidewalls.

Thereafter, an ion implantation process is performed using the photo-resist pattern 126 as an ion implantation mask to form the conductive line regions 120 within the substrate 110. The conductive line regions 120 extend along the first direction DR and are formed by the implantation dopant passing through the openings 127 but being blocked by the photo-resist pattern 125 when suitable ion implantation conditions are set.

Thus, the conductive line regions 120 are disposed under the openings 127 of the photo-resist pattern 126. The width of the conductive line regions 120 is substantially equal to the lower width of the photo-resist pattern 126. The conductive line regions 120 are N⁺ type. Subsequent processes are then performed similarly as described above after formation of the conductive line regions 120.

However in the embodiment of FIGS. 12A, 12B, and 12C, the photo mask 131 used for forming the conductive line regions 120 is the same as for forming the conductive junction region 150. That is, the conductive line regions 120 and the conductive junction region 150 are formed using one photo mask 131 instead of two photo masks for reducing processing cost.

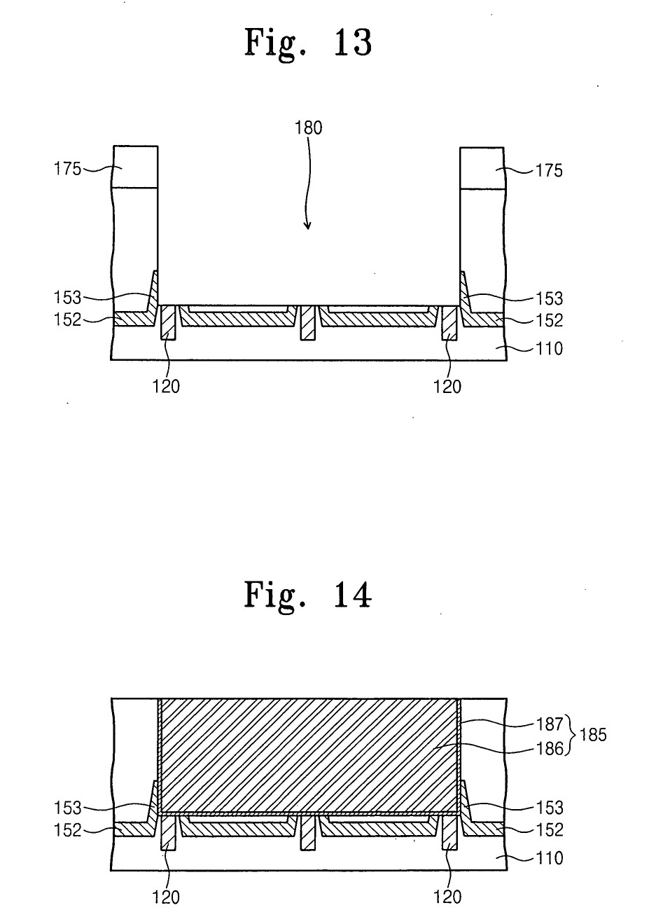

FIGS. 13 and 14 illustrate the method of forming the image sensor as illustrated in the cross-sectional view of FIG. 3 according to another embodiment of the present invention. Referring to FIGS. 1 and 13, after forming a mask pattern 175 on the substrate 110, an etch process is performed to form openings 180 extending along the second direction DC. Each opening 180 penetrates the conductive junction region 150 to expose a plurality of the conductive line regions 120. The present invention may be practiced with the openings 180 formed at either both sides or one side of the conductive line regions 120.

Referring to FIGS. 1 and 14, a bottom contact 185 is formed in the opening 180 with the bottom contact 185 extending along the second direction DC. The bottom contact 185 includes a contact plug 186 and an impurity diffusion layer 187. The impurity diffusion layer 187 surrounds the contact plug 186 and has a different conductivity type (e.g., N⁺ type) from the conductive junction region 150.

The bottom contact 185 is in contact with the conductive line regions 120. The conductive line regions 120 are electrically connected to each other via the bottom contact 185. Subsequent processes may then be performed the same as described in the foregoing embodiments. However in the embodiment of FIG. 14, the number of top contacts formed on the bottom contact 185 may be different from the foregoing embodiments. That is, the number of the top contacts may be set considering the electrical resistance between the top and bottom contacts.

The foregoing embodiments are by way of example only and the present invention is not limited thereto. The order for forming the above described elements may be exchanged with each other. For example, the order for forming the conductive line regions 120 and the conductive junction region 150 may be exchanged. In addition, the order for forming the surrounding junction 170, the bottom contacts 185, and the photo-detectors 115 may be exchanged.

In this manner, the CMOS (complementary metal oxide semiconductor) image sensor of the present invention has a vertical NPN overflow drain structure formed with simple fabrication steps. Furthermore, the CMOS image sensor has a 1-transistor structure for high integration and high fill factor.

Although the present invention has been described in connection with the embodiment of the present invention illustrated in the accompanying drawings, it is not limited thereto. It will be apparent to those skilled in the art that various substitutions, modifications, and changes may be made without departing from the scope and spirit of the invention.

The present invention is limited only as defined in the following claims and equivalents thereof.

What is claimed is:

1. An image sensor comprising:
an array of photo-detectors formed in a semiconductor substrate;
a plurality of conductive line regions formed in the semiconductor substrate, each conductive line region formed under a respective line of photo-detectors along a first direction; and
a conductive junction region formed between the array of photo-detectors and the plurality of conductive line regions within the semiconductor substrate.

2. The image sensor of claim 1, wherein the conductive line regions are doped with a first dopant, and wherein the conductive junction region is doped with a second dopant that is of opposite conductivity from the first dopant.

3. The image sensor of claim 2, wherein each photo-detector has a respective junction region doped with a third dopant of the same conductivity type as the first dopant.

4. The image sensor of claim 3, wherein the semiconductor substrate is doped with a fourth dopant of the same conductivity type as the second dopant.

5. The image sensor of claim 4, wherein the semiconductor substrate is P type doped, wherein the conductive line regions are N+ type doped, wherein the conductive junction region is P+ type doped, and wherein the respective junction regions of the photo-detectors are N type doped.

6. The image sensor of claim 3, wherein each photo-detector has a respective top junction region doped with a fifth dopant of the opposite conductivity type as the third dopant.

7. The image sensor of claim 6, wherein the semiconductor substrate is P type doped, wherein the conductive line regions are N+ type doped, wherein the conductive junction region is P+ type doped, wherein the respective junction regions of the photo-detectors are N type doped, and wherein the respective top junction regions of the photo-detectors are P type doped.

8. The image sensor of claim 3, further comprising:
a surrounding junction that surrounds the array of photo-detectors.

9. The image sensor of claim 8, wherein the semiconductor substrate is P type doped, wherein the conductive line regions are N+ type doped, wherein the conductive junction region is P+ type doped, wherein the respective junction regions of the photo-detectors are N type doped, and wherein the surrounding junction is P+ type doped.

10. The image sensor of claim 1, wherein the conductive junction region is separated from the conductive line regions by a material of the semiconductor substrate.

11. The image sensor of claim 10, wherein the conductive junction region surrounds a portion of the conductive line regions.

12. The image sensor of claim 11, wherein the conductive junction region surrounds a respective top surface, and surrounds respective side portions of each conductive line region with inclined surfaces of the conductive junction region.

13. The image sensor of claim 1, wherein the array of photo-detectors includes:
a respective transmission transistor coupled to the respective junction region of each of the photo-detectors.

14. The image sensor of claim 13, wherein the respective transmission transistor is a respective field effect transistor.

15. The image sensor of claim 1, further comprising:
at least one respective conductive plug formed onto each of the conductive line regions for making contact to the respective conductive line region.

16. The image sensor of claim 15, further comprising:
two respective conductive plugs formed onto two ends of each conductive line region.

17. The image sensor of claim 15, further comprising:
a respective impurity diffusion layer surrounding each conductive plug.

18. The image sensor of claim 15, wherein a conductive plug is formed onto a plurality of conductive line regions.

19. The image sensor of claim 15, further comprising:
an overlying conductive line coupled to a line of conductive plugs disposed along a second direction that is perpendicular to the first direction.

20. The image sensor of claim 19, further comprising:
a surrounding junction that surrounds the array of photo-detectors, wherein the conductive plugs and the overlying conductive line are formed outside of the surrounding junction.
